(19) United States
(12) Patent Application Publication
(10) Pub. No.: US 2008/0191258 A1
(43) Pub. Date: Aug. 14, 2008

(54) LOW VOLTAGE COEFFICIENT MOS CAPACITORS

(75) Inventors: Tan Li JIA, (US); Sanford CHU, (US); Michael CHENG, (US)

Correspondence Address: HORIZON IP PTE LTD, 7500A Beach Road, #04-306/308 The Plaza, SINGAPORE 199591, omitted

(73) Assignee: Chartered Semiconductor Manufacturing, Ltd., Singapore (SG)

(21) Appl. No.: 11/672,971

(22) Filed: Feb. 9, 2007

(51) Int. Cl. H01L 29/94; H01L 21/8242

(52) U.S. Cl. 257/306; 438/253; 257/E21.646; 257/E29.345

(57) ABSTRACT

A low voltage coefficient MOS capacitor includes first and second dielectric layers between first and second capacitor plates, with a common plate separating the dielectric layers. First and second terminals are coupled to first and second capacitor plates.

### FIELD OF THE INVENTION

The present invention relates generally to integrated circuits, and more particularly to low voltage coefficient MOS capacitors.

### BACKGROUND OF THE INVENTION

In integrated circuits (ICs), various components such as transistors, resistors and capacitors are configured to achieve the desired function. Capacitors, for example, are used to store energy elements or filters for differentiating between high-frequency and low-frequency signals. FIG. 1 shows a parallel plate capacitor 100 having first and second terminals 160 and 170. The capacitor includes a pair of closely spaced conductors or plates 112 and 118 separated by a dielectric material 114. The plates are connected to the terminals. When current is passed through the capacitor by a voltage potential applied to the terminals, electric charge of equal magnitude, but opposite sign, build up on each plate.

MOS capacitors are generally employed for complementary metal oxide semiconductor (CMOS) applications. FIGS. 2a-b shows a conventional MOS capacitor 200. Such types of MOS capacitors, for example, are referred to as polysilicon-insulator-silicon (PIS) capacitors. As shown, the capacitor comprises a transistor 110 formed on a semiconductor substrate 105. The area in which the transistor is formed includes a doped well 106. The transistor includes electrodes 211a-b formed in the well and a gate 218 disposed thereon, and separated therefrom by a gate dielectric 214. Shallow trench isolations (STIs) 109 are provided to isolate the capacitor from other components on the substrate. The electrodes serve as a first plate 212 while the gate serves as a second plate. The first and second plates are separated by the gate dielectric, forming a capacitor. First and second terminals 160 and 170 are coupled to respective plates of the capacitor.

Capacitors exhibit a phenomenon called voltage coefficient, in which a change in voltage causes changes in physical characteristics, such as capacitive value. A simulation of capacitance versus voltage of a conventional MOS capacitor was conducted and values plotted in FIG. 3. The device size simulated is 20 μm×20 μm. As evidenced by curve 392, conventional MOS capacitors exhibit high voltage coefficient. The first order voltage coefficient is about −8.6E+03 ppm/V and the second order voltage coefficient is about −7.37E+03 ppm/V². Such high dependency on voltage negatively impacts circuit performance, particularly in analog applications.

From the foregoing discussion, it is desirable to provide capacitors with low voltage coefficient.

### SUMMARY OF THE INVENTION

The present invention relates to low voltage coefficient MOS capacitors. In one aspect, a MOS capacitor is provided. The MOS capacitor comprises a first transistor with first and second electrodes and first gate electrode. The first gate electrode comprises a first gate layer over a gate dielectric. The MOS capacitor also comprises a second transistor comprising third, fourth electrodes and second gate electrode having a second gate layer over a second gate dielectric. First and second terminals are coupled to the first and second transistors, wherein the MOS capacitor has a low voltage coefficient.

In another aspect, a method for forming a MOS capacitor is provided. The method comprises providing a substrate prepared with a capacitor area having a doped well of a first conductivity type and forming dielectric and gate layers on the substrate surface, with the dielectric layer between the substrate and the gate layer. The dielectric and gate layers are patterned to form first and second gates in the capacitor area. Dopants of a second conductivity type are implanted on the substrate to form first, second, third and fourth electrodes, the first and second electrodes and the first gate forming a first transistor, and the third and fourth electrodes and the second gate forming a second transistor. Contacts and connections are formed to couple the transistors with first and second terminals to form the MOS capacitor, wherein the MOS capacitor has a low voltage coefficient.

In yet another aspect, a capacitor is provided. The capacitor comprises first, second and third capacitor plates separated by first and second dielectrics and first and second terminals. The first terminal is coupled to the first capacitor plate and the second terminal is coupled to the second capacitor plate. The third capacitor plate is common to the first and second dielectrics, wherein the capacitor has a low voltage coefficient.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows a parallel plate capacitor;

FIGS. 2a-b show a circuit diagram and cross-section of a conventional MOS capacitor;

FIG. 3 shows a simulated capacitance-voltage curve of a conventional MOS capacitor;

FIGS. 4a-b show a circuit diagram and cross-section of a MOS capacitor in accordance with one embodiment of the invention;

FIG. 4c shows a general structure of a MOS capacitor in accordance with one embodiment of the invention;

FIG. 5 shows a top view of a MOS capacitor in accordance with one embodiment of the invention;

FIGS. 6a-e show a process for forming a MOS capacitor in accordance with one embodiment of the invention;

FIGS. 7a-b show a circuit diagram and cross-section of a MOS capacitor in accordance with another embodiment of the invention;

FIG. 8 shows a top view of a MOS capacitor in accordance with another embodiment of the invention; and

FIG. 9 shows a simulated capacitance-voltage curve of a MOS capacitor in accordance with the invention.

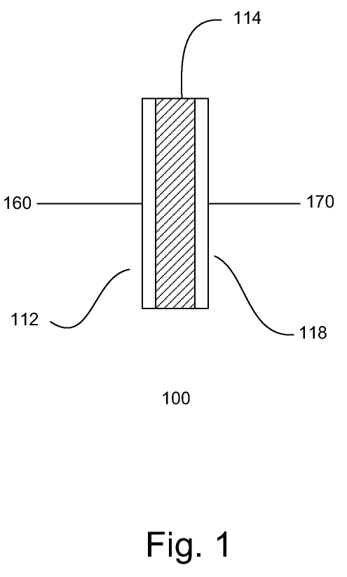

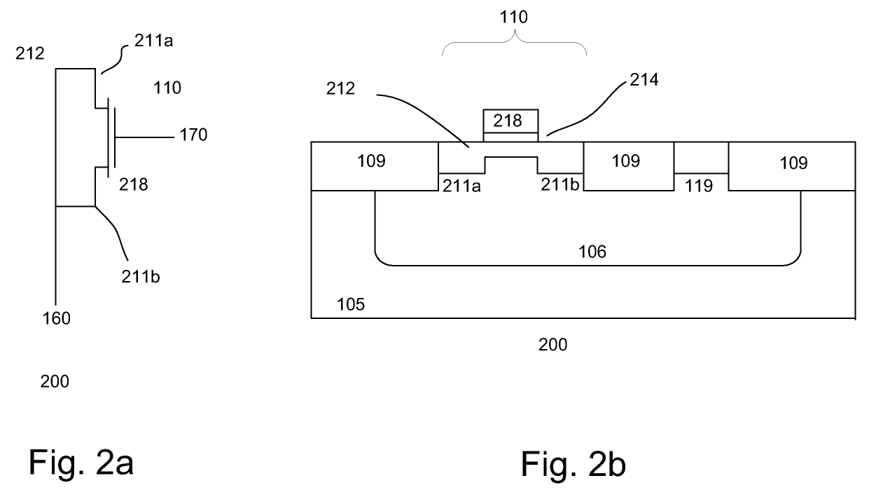

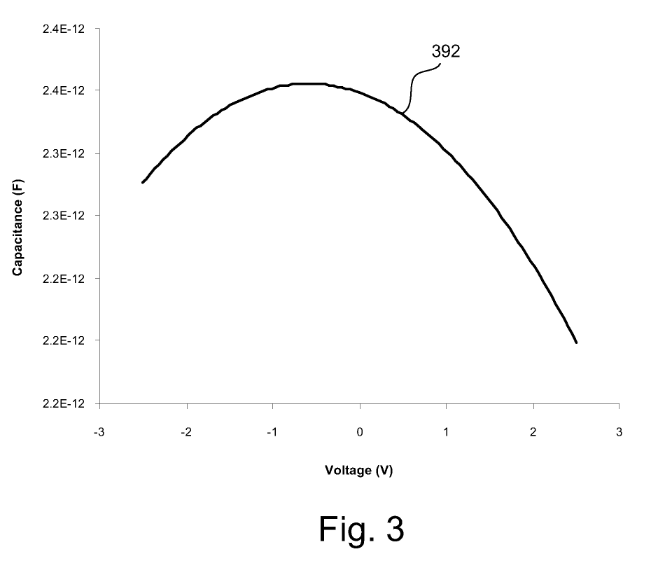

### DETAILED DESCRIPTION OF THE INVENTION

The present invention relates to low voltage coefficient capacitors. In one embodiment, the low voltage coefficient capacitors are MOS capacitors. The low voltage coefficient is achieved, in one embodiment, by compensating for capacitance variations due to different voltages. The MOS capacitors can be incorporated into ICs and easily integrated into current CMOS processing technologies. The ICs can be any type of IC, for example dynamic or static random access memories, signal processors, or system on chip devices, mixed signal or analog devices such as A/D converters and switched capacitor filters. Other types of ICs are also useful. Such ICs are incorporated in, for example, communication systems, consumer products such as communication products or other types of products.

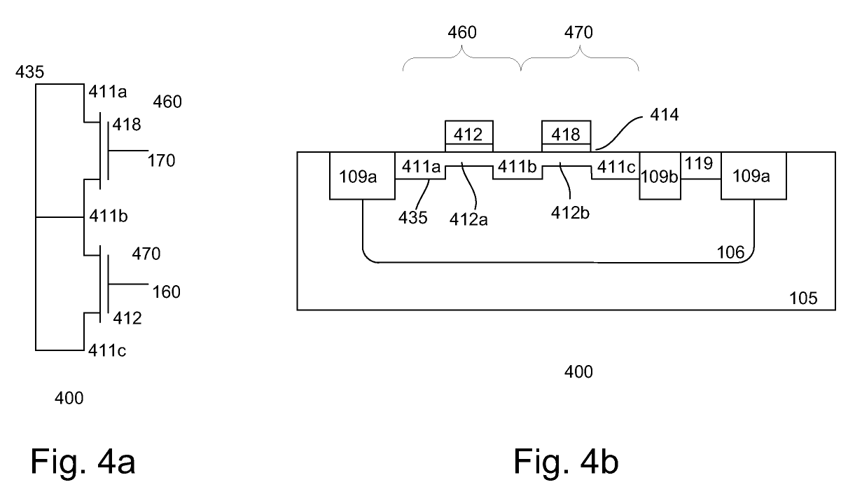

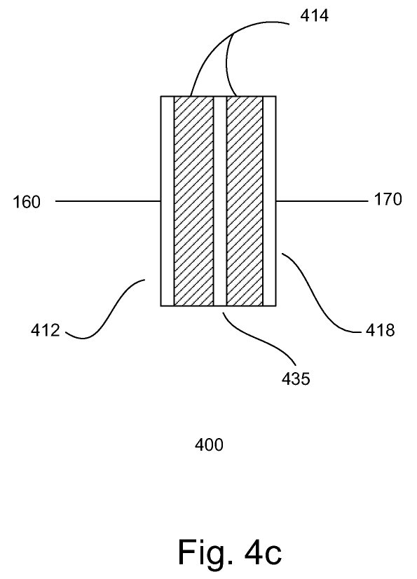

FIGS. 4a-b show a MOS capacitor 400 in accordance with one embodiment of the invention. The MOS capacitor comprises first and second field effect transistors (FETs) 460 and 470. In one embodiment, the FETs comprise a first polarity type. In one embodiment, the first polarity type comprises p-type. Providing FETs of a second polarity type (e.g., n-type) is also useful. The FETs are formed on a substrate. The substrate 105, for example, comprises a semiconductor substrate. In one embodiment, the semiconductor substrate comprises a silicon substrate. The substrate, for example, comprises a lightly doped p-type substrate. Other types of semiconductor substrates are also useful.

In one embodiment, the FETs are formed on a doped well 106. In one embodiment, the doped well comprises a second polarity type. For example, a n-type doped well is provided for p-type FETs. The FETs include gates 412 and 418 formed on the surface of the well. The gates are separated from the substrate by a gate dielectric layer 414. The FETs also include electrodes 411a-c adjacent to the gates. As shown, electrode 411b is shared between the gates of the FETs. A channel is provided under the gate between the electrodes. The channels 412a-b coupled the electrodes, forming a common plate 435. The electrodes and channels are formed by doped regions of the first polarity type. Typically, the channels are formed separately from the electrodes. For example, a separate or extra P⁺ implant is used to form P⁺ channels under the gates between the electrodes for p-type FETs.

STIs 109a are formed in the substrate to isolate the MOS capacitor from other devices. In one embodiment, a doped well guard ring is provided. The guard ring, for example, comprises a doped region 119. The doped region, in one embodiment, comprises a heavily doped region of the second polarity type. In one embodiment, the doped region comprises a heavily doped n-type (N) doped region. The guard ring is located at the edge of the doped well, between STIs 109a and 109b. In one embodiment, the doped well is positively biased via doped region. For example, the doped well is biased with V_{DD}.

A first terminal 160 is coupled to the gate of the first FET and a second terminal 170 is coupled to the gate of the second FET. The gates serve as first and second plates of the capacitor, separated from the common plate by the gate dielectric layers. Structurally, the capacitor comprises first 412, second 418 and third 435 plates separated by first and second dielectric layers 414, as shown in FIG. 4c. A voltage potential is applied to the terminals, causing a current to flow through the capacitor.

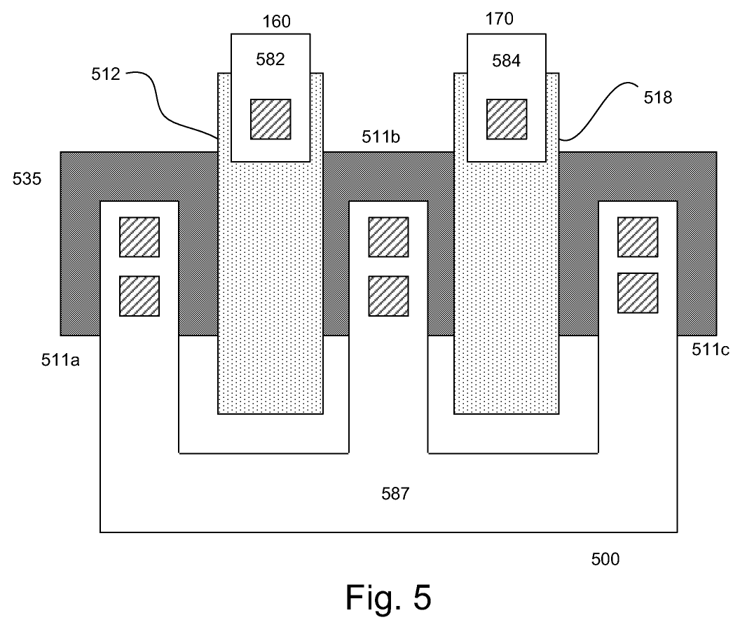

FIG. 5 shows a layout of a capacitor 500 in accordance with one embodiment of the invention. In one embodiment, the capacitor is formed on a doped well. The capacitor includes an elongated common plate 535 formed beneath the surface of a well. First and second gate structures 512 and 518 are formed on the well, intersecting the common plate. Contacts are formed, coupling a conductor 587 to the common plate via electrodes 511a-c located adjacent to the gate structures. Conductors 160 and 170 are respectively coupled to first and second gate structures via contacts 582 and 584.

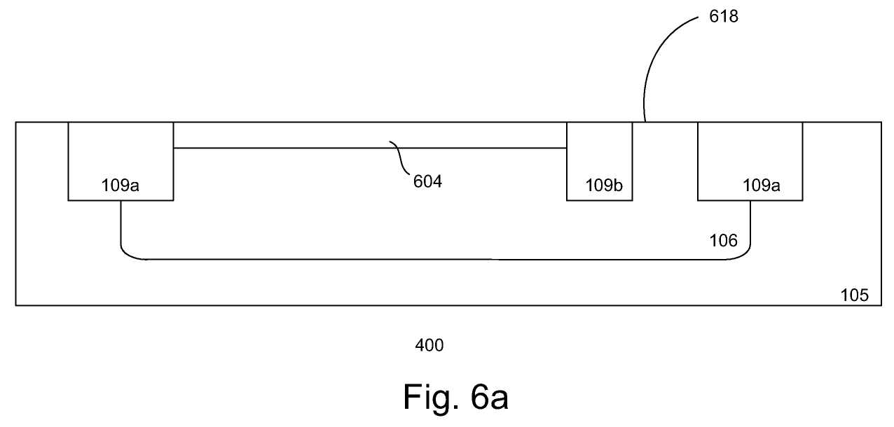

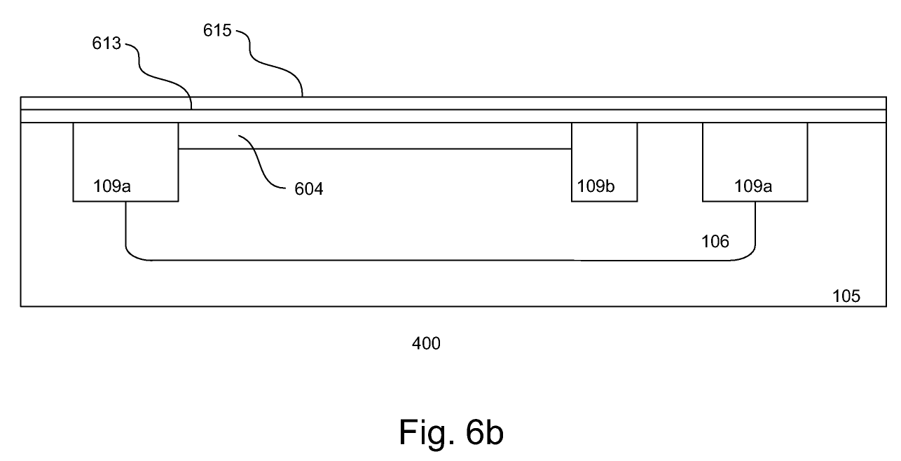

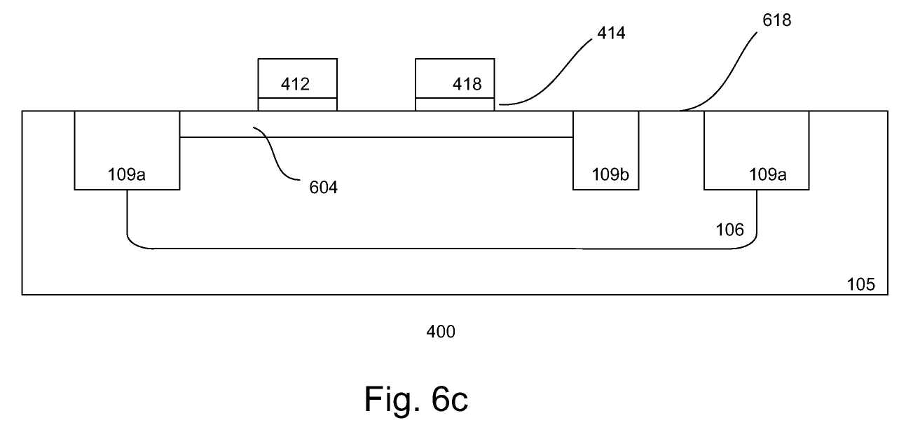

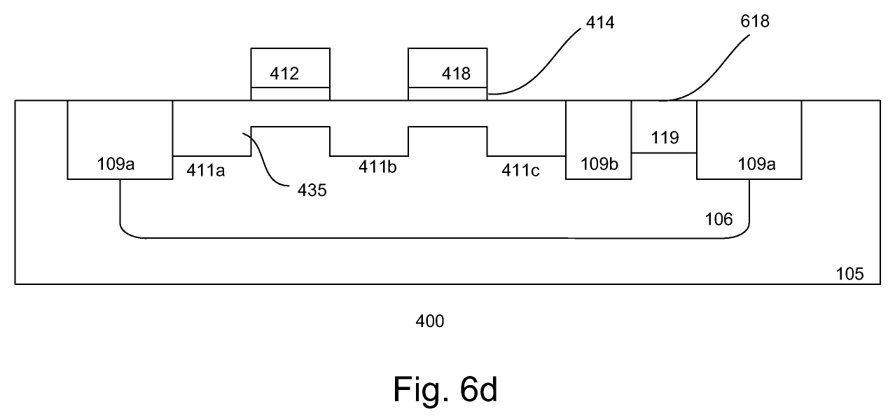

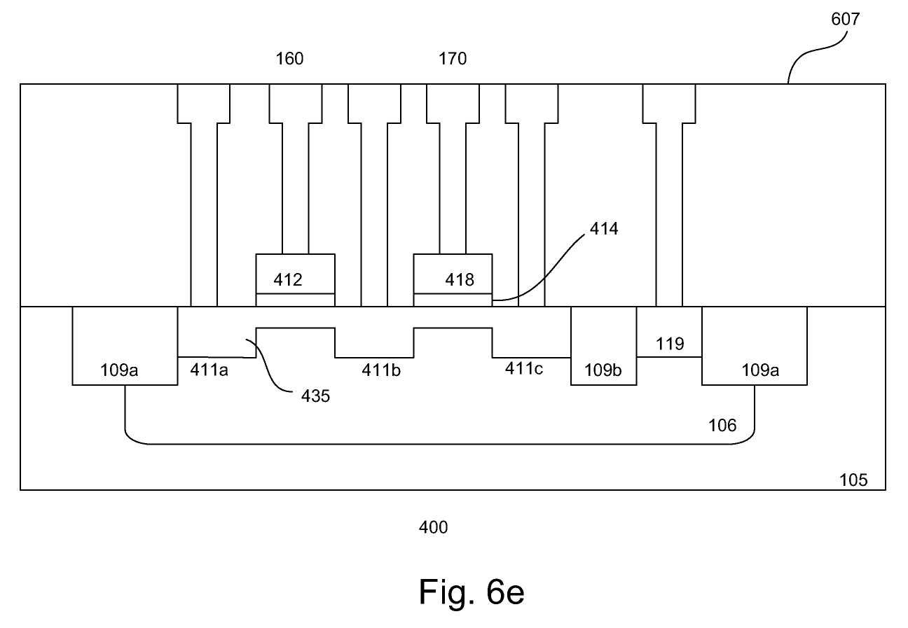

FIGS. 6a-e show a process for forming a MOS capacitor 400 in accordance with one embodiment of the invention. Referring to FIG. 6a, a semiconductor substrate 105 is provided. The substrate, for example, comprises a silicon substrate. Typically, the semiconductor substrate comprises a lightly doped p-type silicon substrate. Other types of semiconductor substrates, for example, silicon-on-insulator, (SOI), SiC, germanium-based including SiGe, SiGeC, and SiGe-on-insulators (SGOIs), or gallium arsenide, are also useful. The substrate is prepared with a doped well 106. The doped well forms the active area for the capacitor. The doped well comprises dopants of a first conductivity type. Preferably the first conductivity type comprises n-type dopants, serving as an active area for pFETs. Various types of n-type dopants can be used, for example, phosphorous, arsenic, antimony or a combination thereof. Providing a p-doped well for nFETs are also useful.

The substrate is further prepared with isolation regions 109a to isolate the capacitor active area from other devices of the IC. The isolation regions preferably comprise STIs. Other types of isolation regions are also useful. In one embodiment, a well guard ring is provided for improving isolation of the capacitor. The guard ring is provided at the edge of the active area of the capacitor. In one embodiment, STI 109b is provided outside of STI 109a, creating a guard ring region 618. The guard ring region is located within the doped well.

The substrate is further prepared with a doped layer 604 on the surface of the substrate. The doped layer comprises dopants of a second conductivity type opposite to the first conductivity type. In one embodiment, the doped layer comprises p-type dopants such as boron, beryllium, magnesium and zinc. The doped layer is formed by, for example, implanting p-type dopants on the surface of the well 106. An implant mask can be provided to selectively form the doped layer in the capacitor region. The implant dose can be, for example, in the range of about 1×10¹⁵ to 4×10¹⁵/cm². Other dosages are also useful.

Referring to FIG. 6b, the process continues by forming a dielectric layer 613 on the substrate. In one embodiment, the dielectric comprises silicon oxide formed by, for example thermal oxidation. Forming other types of dielectric layers is also useful. The thickness of the dielectric layer typically is about 30 to 300 Å. Other thicknesses may also be useful. A gate layer 615 is deposited on the substrate over the dielectric layer. The gate layer, in one embodiment, comprises polysilicon. The polysilicon, for example, comprises LP-CVD in-situ doped or un-doped polysilicon. Other types of gate layers are also useful. The gate and dielectric layers are then patterned to form first and second gates 412 and 418, as shown in FIG. 6c. The gates are patterned using, for example, conventional lithographic and etch processes. Channels are provided under the gates by doped layer 604.

In FIG. 6d, the process continues by forming electrodes 411a-c and guard ring or well contact 119 in the guard ring region 618. The electrodes comprise dopants of the second conductivity type and the well contact comprises dopants of the first conductivity type. In one embodiment, the electrodes comprise p-type dopants while the well contact region comprises n-type dopants. The electrodes and the well contact can be formed using two separate dopant implantation steps. For example, a first implantation step forms the electrodes and the P⁺ region for the other components and a second implantation step forms the well contact and the N⁺ region for the other components. Separate implant masks can be used to form the electrodes and the well contact region. The implant dose can be, for example, in the range of about 1×10¹⁵ to 4×10¹⁵/cm².

Referring to FIG. 6e, a dielectric layer 607 is formed, covering the substrate and the transistors. Contacts and trenches are formed in the dielectric layer, forming connections to the gates and electrodes. In one embodiment, a first capacitor terminal 160 is coupled to the first gate and the second capacitor terminal 170 is coupled to the second gate. The electrodes are commonly coupled by a conductor (not shown). In one embodiment, the well contact is coupled to the well guard ring and is positively biased.

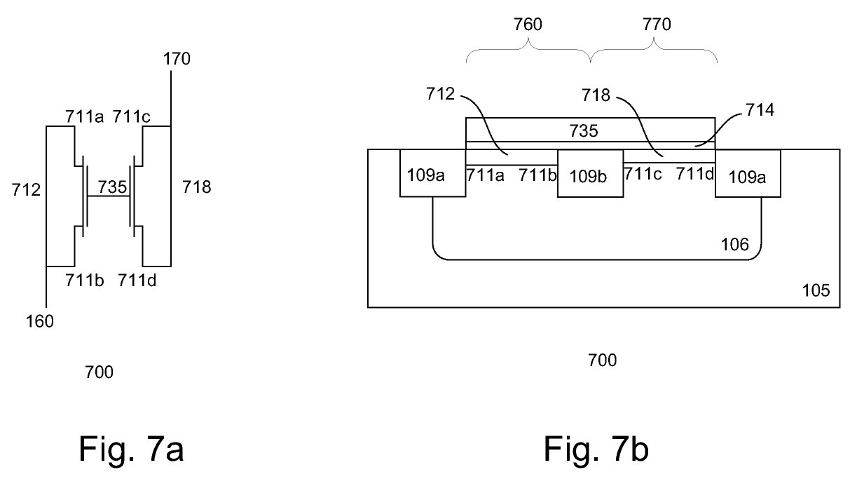

FIGS. 7a-b show a MOS capacitor 700 in accordance with another embodiment of the invention. The MOS capacitor comprises first and second field effect transistors (FETs) 760 and 770. The FETs are formed on a semiconductor substrate 105 in an area which includes a doped well 106. Preferably, the doped well comprises a n-well and the FETs are pFETS. The FETs include a common gate 735 formed on the surface of the well, separated by a gate dielectric layer 714. The common gate is shared by the FETs. Electrodes 711a-d are disposed on the well adjacent to the common gate. The electrodes of the first and second transistors are coupled by a channel under the common gate forming plates 712 and 718. Isolations 109a, such as STIs, are formed in the substrate to isolate the capacitor from other devices. STI 109b isolates the first and second FETs.

A first terminal 160 is coupled to the electrodes of the first FET and a second terminal 170 is coupled to the electrodes of the second FET. The electrodes of first and second FETs serve as first and second plates of the capacitor. The gate serves as a common plate between the two plates and separated by the gate dielectric. A voltage potential is applied to the terminals, causing a current to flow through the capacitor.

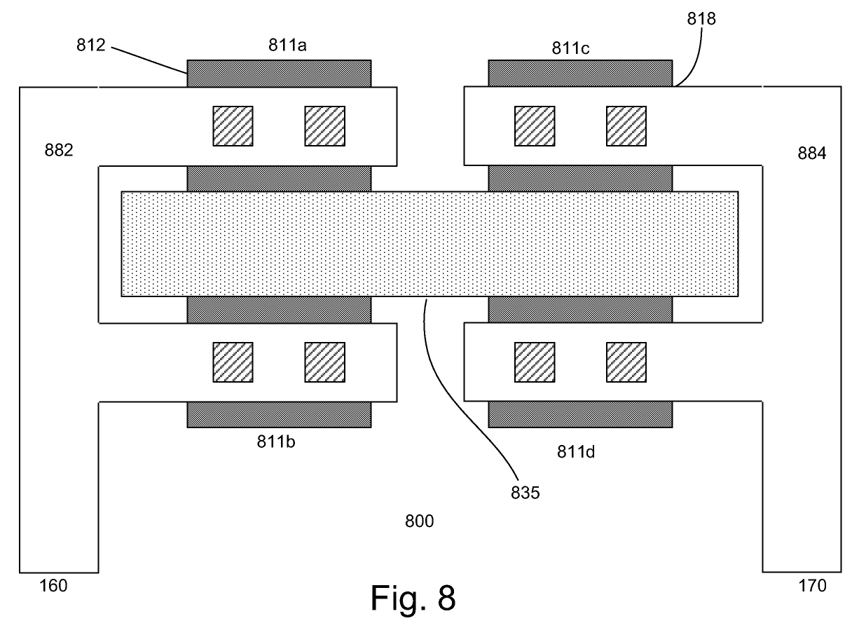

FIG. 8 shows a layout of a capacitor 800 in accordance with one embodiment of the invention. In one embodiment, the capacitor is formed on a doped well. The capacitor includes first and second elongated plates 812 and 818 disposed beneath the surface of the well. The plates are formed by electrodes 811a-b and 811c-d of the transistors. Contacts are formed, coupling a first conductor 882 to the first plate 812 via electrodes 811a-b and a second conductor 884 to the second plate 818 via electrodes 811c-d. The first and second conductors correspond to first and second terminals 160 and 170, respectively. A common gate 835 is formed on the surface of the substrate.

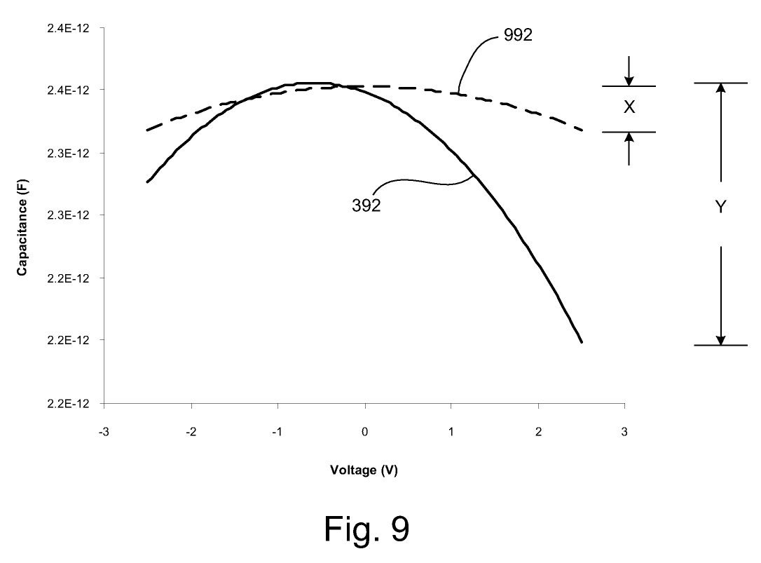

A simulation was conducted to compare the voltage dependency of a conventional MOS capacitor with one in accordance with the present invention. The present MOS capacitor was simulated with a device size of 40 μm×20 μm while the conventional MOS capacitor was simulated with a device size of 20 μm×20 μm. The simulated capacitance-voltage (C-V) curves are shown in FIG. 9. The results of the MOS capacitor in accordance with the invention are plotted as curve 992 and the results of the conventional MOS capacitor are plotted as curve 392. As evidenced by the curves, the MOS capacitor of the present invention has a capacitance variance X which is less than capacitance variance Y of the conventional MOS capacitor.

Table 1 shows the voltage coefficient values for conventional MOS capacitors (VC1_{Y} and VC2_{Y}) and that of the present invention (VC1_{X} and VC2_{X}). As compared to conventional MOS capacitors, the present invention has a significantly smaller voltage dependency. In particular, the first order voltage coefficient VC1_{X} is decreased by more than 3 orders in magnitude compared to VC1_{Y}. The second order voltage coefficient VC2_{X} is decreased by up to 70% compared to VC2_{Y}.

TABLE 1

| (ppm/V) | (ppm/V²) |
|---|---|
| VC1_{X} = 1.38E+00 | VC2_{X} = −1.89E+03 |
| VC1_{Y} = −8.6E+03 | VC2_{Y} = −7.37E+03 |

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A MOS capacitor comprising:
a first transistor comprising first and second electrodes and first gate electrode, the first gate electrode including a first gate dielectric;
a second transistor comprising third, fourth electrodes and second gate electrode, the second gate electrode including a second gate dielectric; and
first and second terminals coupled to the first and second transistors, the first and second transistors form the MOS capacitor, wherein the MOS capacitor has a low voltage coefficient.

2. The MOS capacitor of claim 1 wherein the first and second transistors comprise first polarity type transistors formed on a doped well of a second polarity type on a substrate.

3. The MOS capacitor of claim 2 is incorporated into an IC.

4. The MOS capacitor of claim 2 is incorporated into a consumer product.

5. The MOS capacitor of claim 2 wherein the first polarity type comprises p-type and the second polarity type comprises n-type.

6. The MOS capacitor of claim 5 further comprises a well contact to the doped well for a well guard ring, the well contact comprises a bias voltage for positively biasing the doped well.

7. The MOS capacitor of claim 1 is incorporated into an IC.

8. The MOS capacitor of claim 1 is incorporated into a consumer product.

9. The MOS capacitor of claim 1 further comprises a well contact to a doped well for a well guard ring, the well contact comprises a bias voltage for positively biasing the doped well.

10. The MOS capacitor of claim 1 wherein the low voltage coefficient is achieved by compensating variation in capacitance due to different voltages.

11. The MOS capacitor of claim 1 wherein the first and second transistors form a MOS capacitor comprising:
first and second capacitor plates;
first and second capacitor dielectric layers between the capacitor plates;
a common plate separating the first and second capacitor dielectric layers; and
wherein the first terminal is coupled to the first plate and the second terminal is coupled to the second plate.

12. The MOS capacitor of claim 11 wherein:
the electrodes comprise doped regions adjacent the gates, the second and third electrodes comprise a common electrode, the first, fourth and common electrodes are coupled to form the common plate;
the first and second gate electrodes form the first and second capacitor plates; and
the first and second gate dielectric layers serve as the first and second dielectric layers of the capacitor.

13. The MOS capacitor of claim 12 wherein the first, fourth, and common electrodes are coupled by first and second doped channels below first and second gate electrodes.

14. The MOS capacitor of claim 11 wherein:
the first and second gate electrodes comprise a common gate electrode, the common gate electrode serving as the common plate;
the first and second electrodes located on opposite sides of a first portion of the common gate electrode, the first and second electrodes are coupled to form the first capacitor plate;
the third and forth electrodes located on opposite sides of a second portion of the gate electrode, the third and fourth electrodes are coupled to form the second capacitor plate, wherein the electrodes comprise doped regions; and
the gate dielectric layers at the first and second portions of the gate electrode serve as the first and second dielectric layers of the capacitor.

15. The MOS capacitor of claim 14 wherein the first and second electrodes are coupled by a first doped channel under the first portion of the gate electrode and the third and fourth electrodes are coupled by a second doped channel under the second portion of the gate electrode.

16. A method for forming a MOS capacitor comprising:
providing a substrate prepared with a capacitor area having a doped well of a first conductivity type;
forming dielectric and gate layers on the substrate surface, with the dielectric layer between the substrate and the gate layer;
patterning the dielectric and gate layers to form first and second gates in the capacitor area;
implanting dopants of a second conductivity type on the substrate to form first, second, third and fourth electrodes, the first and second electrodes and the first gate forming a first transistor, and the third and fourth electrodes and the second gate forming a second transistor; and
forming contacts and connections to couple the transistors with first and second terminals to form the MOS capacitor, wherein the MOS capacitor has a low voltage coefficient.

17. A capacitor comprising:
first, second and third capacitor plates separated by first and second dielectrics; and
first and second terminals, the first terminal is coupled to the first capacitor plate, the second terminal is coupled to the second capacitor plate, the third capacitor plate is common to the first and second dielectrics, wherein the capacitor has a low voltage coefficient.
